(19) United States
(12) Patent Application Publication
(10) Pub. No.: US 2026/0110408 A1
(43) Pub. Date: Apr. 23, 2026

(54) WATERPROOF LIGHT-EMITTING DIODE PLUG-IN LIGHT AND METHOD OF MAKING THEREOF

(71) Applicant: DONGGUAN YONGFENG LIGHTING CO., LTD, Dongguan (CN)

(72) Inventor: ZHUMEI DENG, Dongguan City (CN)

(21) Appl. No.: 19/267,240

(22) Filed: Jul. 11, 2025

Related U.S. Application Data
(63) Continuation-in-part of application No. 18/923,600, filed on Oct. 22, 2024.

(51) Int. Cl. F21K 9/90; F21S 4/10; F21V 23/00; F21V 23/06; F21V 31/00; F21Y 115/10; H05K 3/34

(52) U.S. Cl. CPC F21K 9/90; F21S 4/10; F21V 23/001; F21V 23/06; F21V 31/005; H05K 3/3421; F21Y 2115/10; H05K 2201/10628

(57) ABSTRACT

A method of making a Surface Mount Device (SMD) light-emitting diode (LED) light is disclosed, the method includes: providing a circuit board; mounting one or more SMD LED chips on the circuit board; coating the SMD LED chips with phosphor; providing a first wire and a second wire, each with an exposed copper end; connecting the exposed copper ends of the first and second wires onto copper traces of the circuit board to form a first partially-finished assembly; assembling a light holder onto the first partially-finished assembly; inserting a rear plug in a space between the first and second wires into the light holder to form a second partially-finished assembly; placing a decorative shell from the top into the second assembly to form a third partially-finished assembly; and applying ultraviolet waterproof glue to gaps at the top and bottom of the third partially-finished assembly to provide waterproof and fixation.

### CROSS-REFERENCE

This application claims the priority of U.S. patent application Ser. No. 18/923,600, filed on Oct. 22, 2024, the entirety of both applications is hereby incorporated by reference.

### FIELD

This relates to light strings, and more particularly, to a Surface Mount Device (SMD) light-emitting diode (LED) plug-in light string with certain waterproof properties.

### BACKGROUND

Traditional LED light strings with waterproof properties are difficult and expensive to manufacture on a large scale and have relatively short service lifespans.

### SUMMARY

In one aspect, this disclosure relates to a SMD LED plug-in light string with certain waterproof properties. In another aspect, the disclosure relates to a method of making such SMD LED plug-in light string with certain waterproof properties.

### BRIEF DESCRIPTION OF THE DRAWINGS

FIGS. 1A, 1B, 2, 3A, 3B, 4A, 4B, 5A, 5B, 6A, 6B, 7A, 7B, 8A, 8B, 8C, 9A, 9B, 10A, 10B, and 11 illustrate the exemplary steps in manufacturing SMD LED plug-in light string with certain waterproof properties, according to an embodiment of the disclosure.

FIGS. 12A and 12B illustrate an exemplary SMD LED that can be used in the making of a plug-in light string, according to an embodiment of the disclosure.

FIGS. 13-20 illustrate the exemplary steps in the making of a SMD LED light string, according to another embodiment of the disclosure.

### DETAILED DESCRIPTION

Embodiments of the present disclosure will be described below in conjunction with the accompanying drawings, but it should be appreciated by those skilled in the art that the embodiments described below are exemplary, rather than exhaustive. They are only used to illustrate the present disclosure and should not be regarded as limiting the scope of the present disclosure. All other embodiments obtained by those of ordinary skill in the art without creative efforts based on the embodiments disclosed herein shall fall within the scope of the present disclosure.

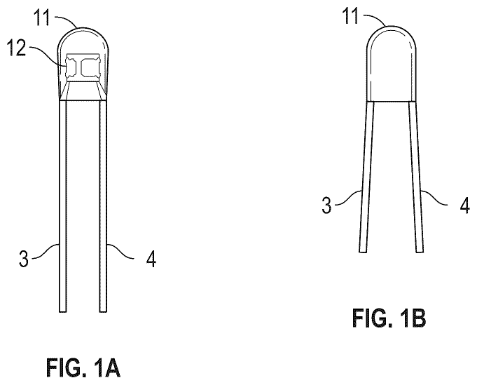

FIGS. 1A, 1B, 2, 3A, 3B, 4A, 4B, 5A, 5B, 6A, 6B, 7A, 7B, 8A, 8B, 8C, 9A, 9B, 10A, 10B, and 11 illustrate the exemplary steps in the making of a SMD LED light string, according to an embodiment of the disclosure. As shown in FIG. 1a, the positive and negative poles of a SMD 12 are respectively welded on two metal conductors 3, 4. FIGS. 12A and 12B illustrate the positive pole 23 and negative pole 24 of an exemplary SMD 22 such as the one used in the step of FIG. 1. Although FIG. 1a shows that the positive and negative poles of the SMD 12 are welded to the end of the metal conductors 3, 4, respectively, it should be understood that the SMD 12 can be welded to any other parts of the metal conductors 3, 4. The SMD can then be encapsulated with a colloid 11 to form an SMD LED 1, as shown in FIG. 1b.

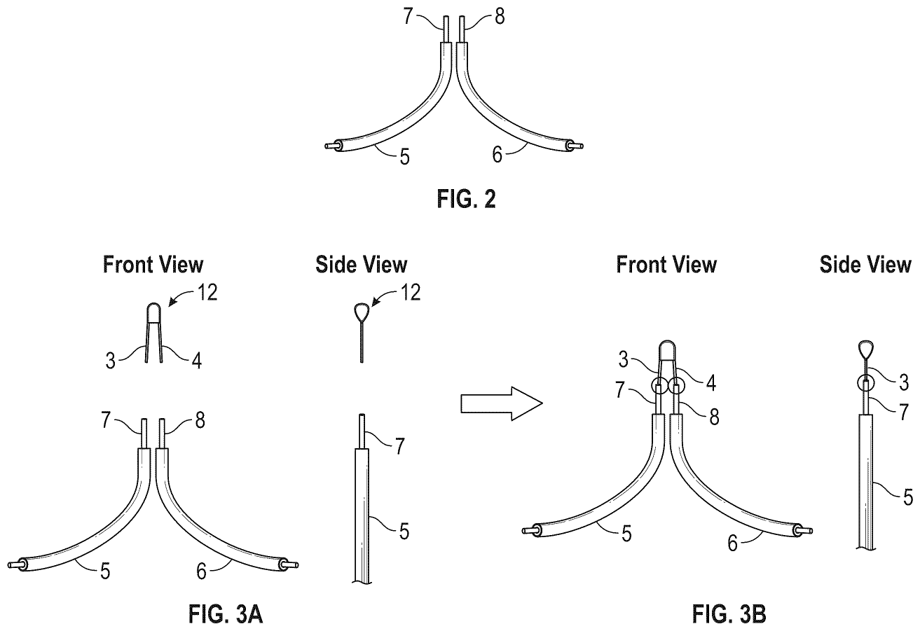

Next, as shown in FIG. 2, two wires 5, 6 are provided. One end of each of the wires 5, 6, have the insulation stripped off to expose the copper wires 7, 8 inside. Additionally, the copper wires 7, 8 can be thinned to facilitate subsequent welding if necessary.

As shown in FIGS. 3a and 3b, the SMD 12 of FIG. 1b can be connected to the exposed ends 7, 8 of wires 5, 6 by welding or any other suitable means such as metal terminals or riveting metal plates. Specifically, each of the metal conductors 3, 4 of the SMD 12 is connected to one of the wires 5, 6, as shown in FIG. 3b.

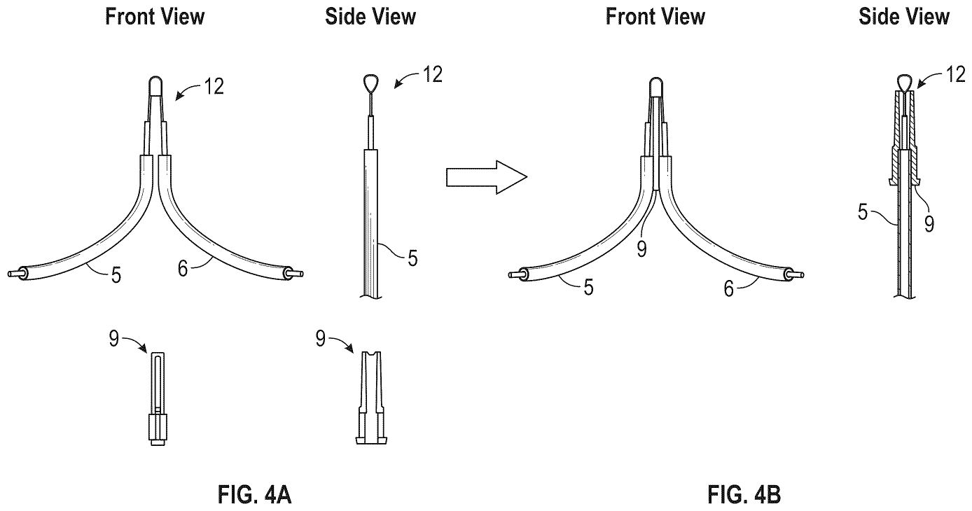

Next, as illustrated in FIGS. 4a and 4b, a rear plug 9 is inserted in a space between the two wires 5, 6, where the wires 5, 6 converge. As illustrated in the side views of FIGS. 4a and 4b, the rear plug 9 can at least partially encapsulate the ends of the wires 5, 6, connected to the SMD LED 12.

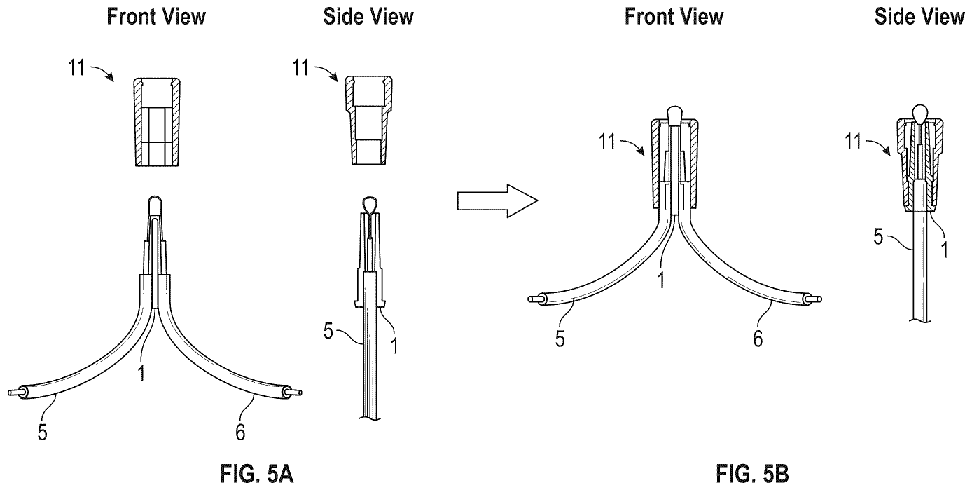

At this stage, there are two different ways to complete the SMD LED assembly. In the first embodiment, the partially-finished assembly of FIG. 4b can be inserted into a lamp holder 11, as illustrated in FIGS. 5a and 5b. A snap joint 1 can optionally be used for stabilizing the assembly within the lamp holder 11. For example, as illustrated in FIG. 5b, the snap joint 1, once inserted into the lamp holder 11, can prevent the wires 5, 6 from moving in some or all directions.

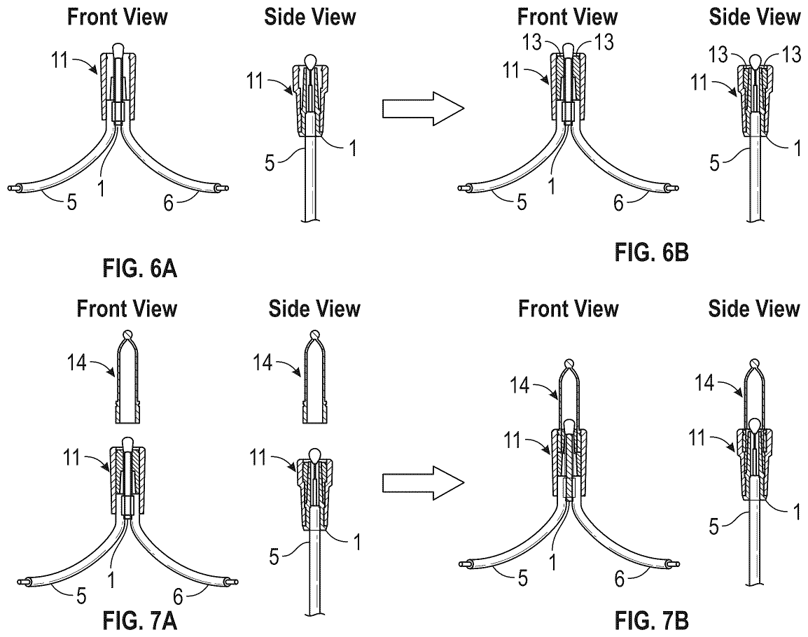

The next step in the first embodiment is illustrated in FIGS. 6a and 6b. In this step, waterproof glue 13 can fill the space inside the lamp holder 11. Referring to FIGS. 7a and 7b, after filling the waterproof glue, but before the glue 13 dries, ornament 14 is placed and secured on the lamp holder 11. Here, the bottom portion of the ornament 14 can fit securely within the lamp holder 11. Ornament 14 can be of different shapes and materials (plastic, glass, etc.). If waterproof glue is not needed, ornament 14 can be added to the assembly after the step shown in FIGS. 5a and 5b is completed, skipping the step of FIGS. 6a and 6b. FIG. 7b illustrates the final assembly of an SMD LED 30.

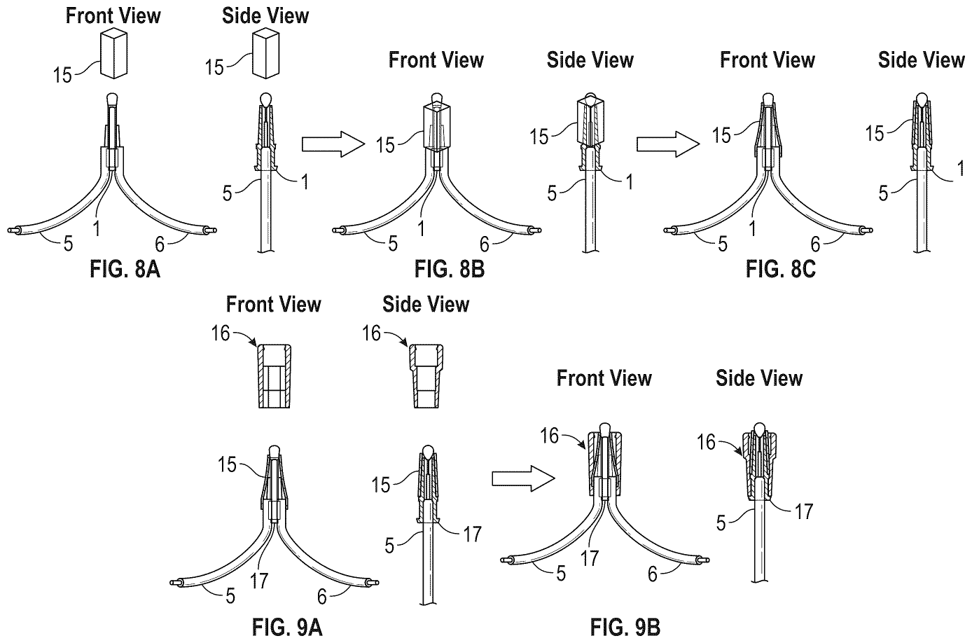

In a second embodiment, after the step of FIGS. 4a and 4b is completed, a heat shrink tubing 15 can be placed over the partially-finished assembly of FIG. 4b (see FIGS. 8a and 8b). The heat shrink tubing can shrink, when heated, to wrap the partially-finished assembly, as shown in FIG. 8c.

Continuing the process of the second embodiment, as illustrated in FIGS. 9a and 9b, the partially-finished assembly of FIG. 8c can be inserted into one end (e.g., tail end) of a lamp holder 16 and secured by snap joint 17 to prevent the partially-finished assembly from moving in one or more directions.

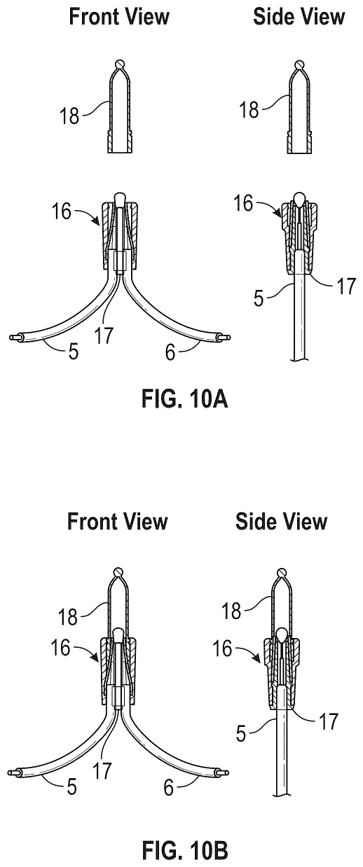

Next, ornament 18 can be added to the partially-finished assembly shown in FIG. 9b. As shown in FIG. 10b, the bottom of the ornament 18 can be inserted and secured between the lamp holder 16 and the heat shrink tubing wrapped SMD LED 1. FIG. 10b shows the final assembly of the SMD LED 32.

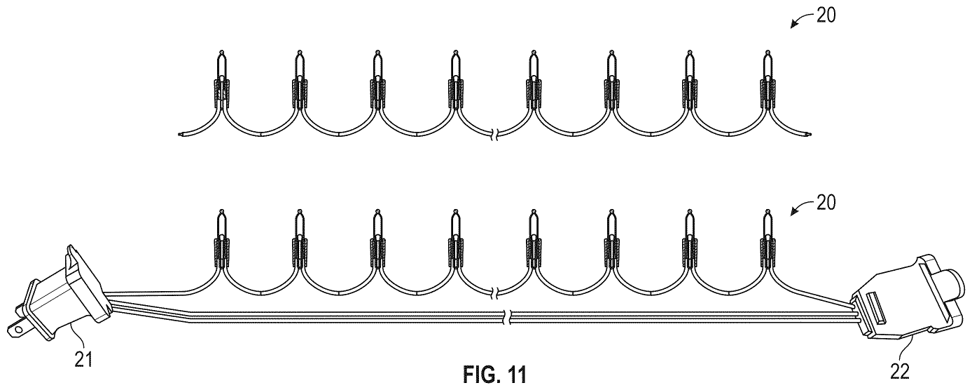

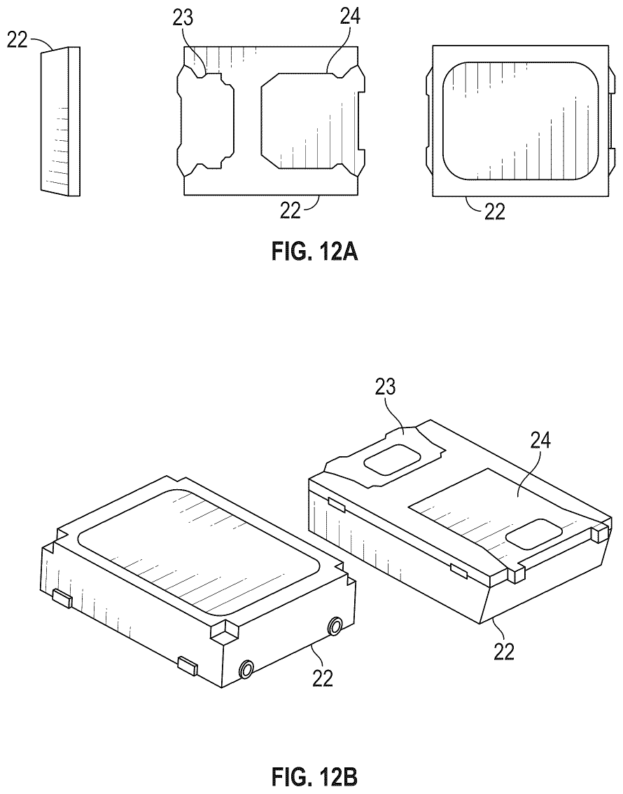

A complete light string 20 can be made by connecting in series multiple SMD LED assemblies such as the ones shown in FIGS. 7b and/or 10b made according to the first and second embodiments, respectively. Front and rear plugs 21, 22, can be added to the light string 20, as illustrated in FIG. 11.

The SMD LED used in the embodiments described above can be SMD LEDs of the various sizes available on the market (e.g., 0603, 0805, 2025 SMD LEDs).

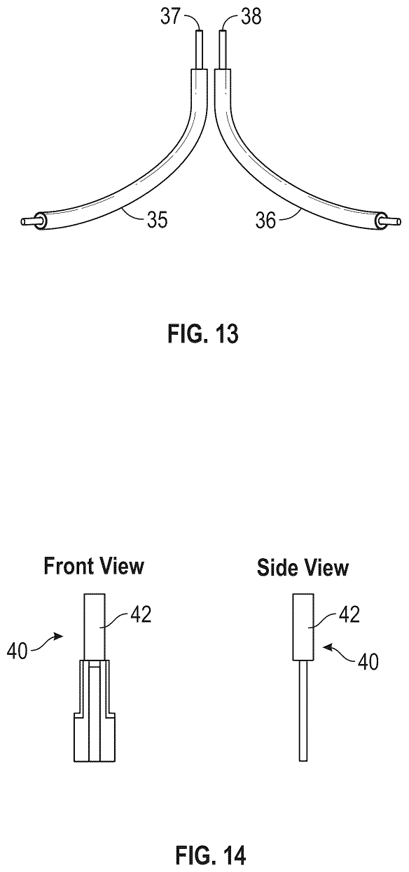

FIGS. 13-20 illustrate the exemplary steps in the making of a SMD LED light string, according to another embodiment of the disclosure.

First, as shown in FIG. 13, two wires 35, 36 are provided. One end of each of the wires 35, 36, have the insulation stripped off to expose the copper wires 37, 38 inside. Additionally, the copper wires 37, 38 can be thinned to facilitate subsequent welding if necessary.

A circuit board 40 is provided. As shown in FIG. 14, one or more SMD LED chips can be mounted on the circuit board 40 and coated with phosphor 42.

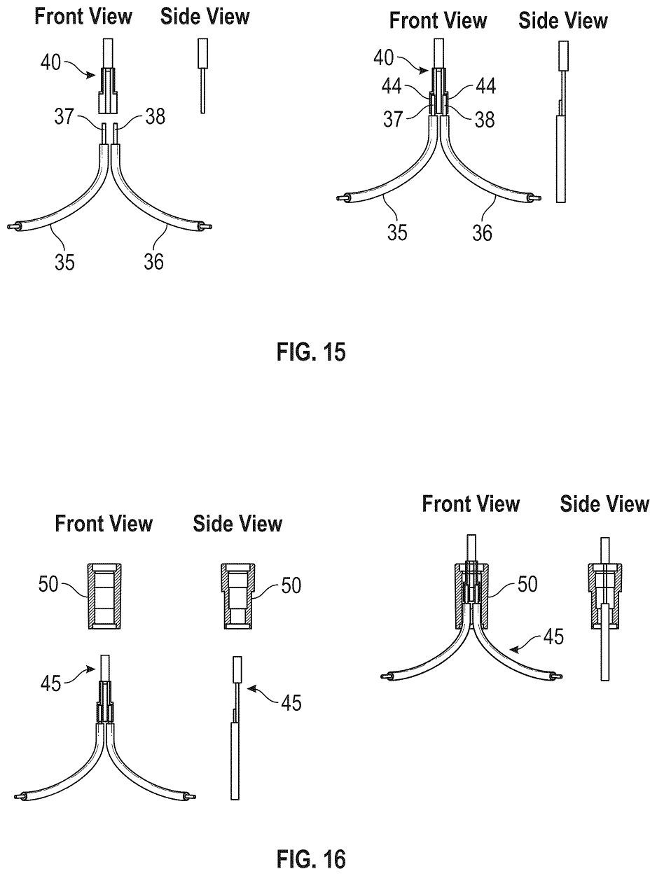

Next, as illustrated in FIG. 15, the exposed copper ends 37, 38 of wires 35, 36 in FIG. 13 are soldered onto the copper traces 44 of the circuit board 40 to form a partially-finished assembly 45.

A light holder 50 is then assembled onto the partially-finished assembly 45, as shown in FIG. 16.

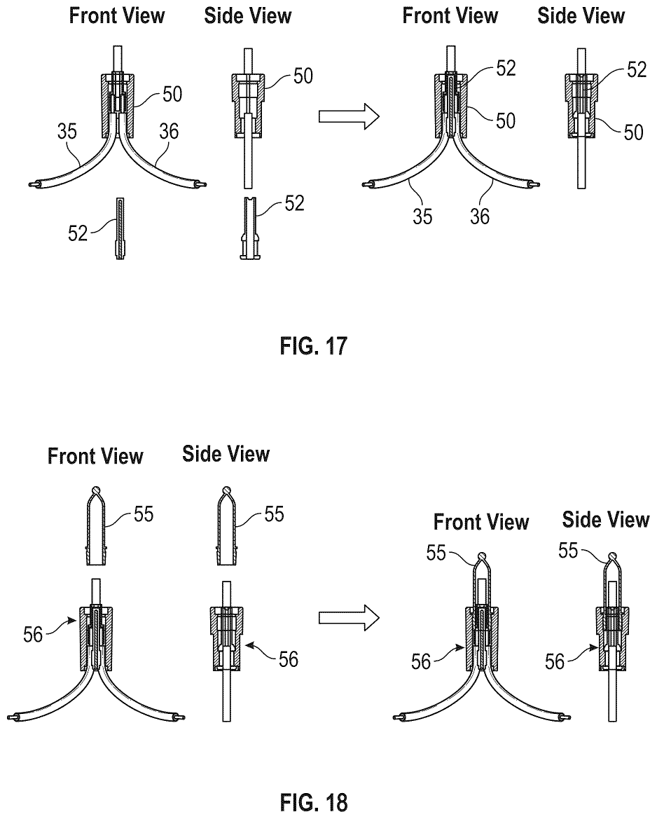

Next, a plug 52 is then inserted between the wires 35, 36 into the light holder 50, as shown in FIG. 17.

Referring to FIG. 18, a decorative shell 55 can be placed from the top into the assembly 56 shown in FIG. 16. The decorative shell 55 can be secured in the light holder 50. The decorative shell can be of different shapes in different embodiments.

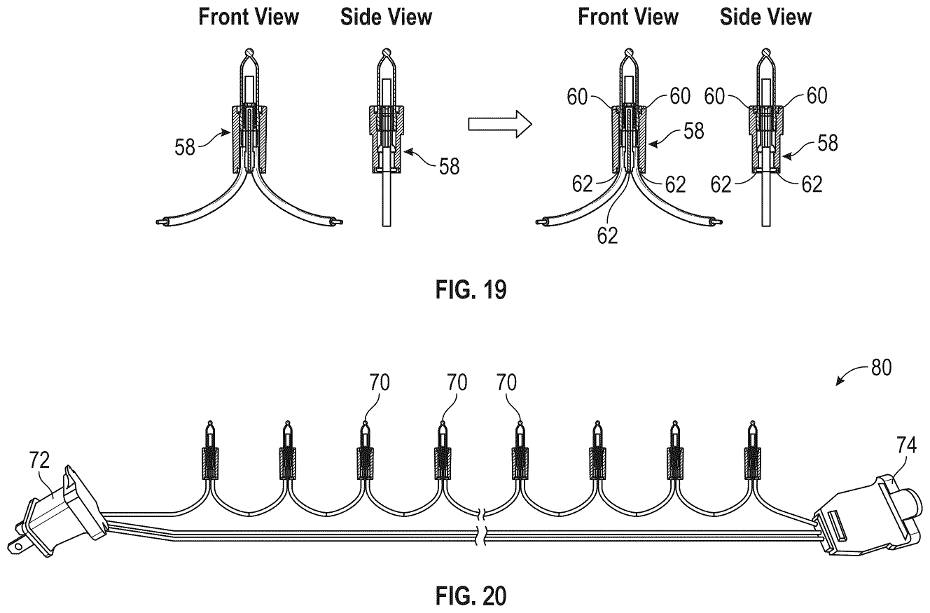

Next, as illustrated in FIG. 19, ultraviolet (UV) waterproof glue can be applied to the gaps 60, 62 at the top and bottom of the assembly 58 of FIG. 17 to provide waterproof and fixation.

Finally, as shown in FIG. 20, by connecting multiple light assemblies 70 of FIG. 18 in series, and with a front plug 72 and a tail plug 74, a complete light string 80 with series-then-parallel connections can be made.

Although embodiments of this disclosure have been fully described with reference to the accompanying drawings, it is to be noted that various changes and modifications will become apparent to those skilled in the art. Such changes and modifications are to be understood as being included within the scope of embodiments of this disclosure as defined by the appended claims.

What is claimed is:

1. A method of making a Surface Mount Device (SMD) light-emitting diode (LED) light, the method comprising:
providing a circuit board;
mounting one or more SMD LED chips on the circuit board;
coating the SMD LED chips with phosphor;
providing a first wire and a second wire, each with an exposed copper end;
connecting the exposed copper ends of the first and second wires onto copper traces of the circuit board to form a first partially-finished assembly;
assembling a light holder 50 onto the first partially-finished assembly;
inserting a rear plug in a space between the first and second wires into the light holder to form a second partially-finished assembly;
placing a decorative shell from the top into the second assembly to form a third partially-finished assembly; and
applying ultraviolet (UV) waterproof glue to gaps at the top and bottom of the third partially-finished assembly to provide waterproof and fixation.

2. The method of claim 1, further comprising securing the decorative shell in the light holder.

3. The method of claim 1, further comprising connecting plurality of the SMD LED lights in series, and with a front plug and a tail plug to form a light string with series-then-parallel connections.

4. The method of claim 1, wherein connecting the exposed copper ends of the first and second wires onto copper traces of the circuit board to form a first partially-finished assembly comprises soldering the exposed copper ends of the first and second wires onto copper traces of the circuit board to form a first partially-finished assembly.

5. A light assembly of a string light comprising:
a circuit board comprising copper traces;
one or more SMD LED chips mounted on the circuit board and coated with phosphor;
a first wire and a second wire, each with an exposed copper end, each of the exposed end connected to the copper traces of the circuit board;
a light holder holding the circuit board connected to the first and second wires;
a rear plug in a space between the first and second wires;
a decorative shell secured on a top portion of the light holder; and
ultraviolet (UV) waterproof glue sealing one or more top gaps between the decorative shell and the light holder and one or more bottom gaps among the decorative shell, the rear plug, and the decorative shell.
